(19) United States
(12) Patent Application Publication
(10) Pub. No.: US 2017/0125261 A1
(43) Pub. Date: May 4, 2017

(54) METHOD OF ETCHING TRANSITION METAL FILM AND SUBSTRATE PROCESSING APPARATUS

(71) Applicant: TOKYO ELECTRON LIMITED, Tokyo (JP)

(72) Inventors: Ryo MIYAMA, Miyagi (JP); Kazuki MOYAMA, Miyagi (JP); Toshihisa NOZAWA, Tokyo (JP)

(73) Assignee: TOKYO ELECTRON LIMITED, Tokyo (JP)

(21) Appl. No.: 15/333,323

(22) Filed: Oct. 25, 2016

(30) Foreign Application Priority Data
Oct. 28, 2015 (JP) 2015-211809

(51) Int. Cl. H01L 21/311; H01L 21/67; H01L 21/02

(52) U.S. Cl. CPC H01L 21/31122; H01L 21/02244; H01L 21/31144; H01L 21/67069; H01L 43/12

(57) ABSTRACT

Disclosed is a method of anisotropically etching a transition metal film using a substrate processing apparatus including at least one processing container configured to perform a processing on a workpiece including the transition metal film. The method includes an oxidation step of introducing a first gas containing an oxygen ion into the processing container and irradiating the transition metal film with the oxygen ion to oxidize a transition metal of the transition metal film, thereby forming a metal oxide layer; and a complexation/etching step of introducing a second gas for complexation of the metal oxide layer into the processing container and forming a metal complex in the metal oxide layer, thereby performing an etching.

### CROSS-REFERENCE TO RELATED APPLICATIONS

This application is based on and claims priority from Japanese Patent Application No. 2015-211809 filed on Oct. 28, 2015 with the Japan Patent Office, the disclosure of which is incorporated herein in its entirety by reference.

### TECHNICAL FIELD

The present disclosure relates to a method of etching a transition metal film and a substrate processing apparatus.

### BACKGROUND

In manufacturing semiconductor devices, an etching processing is performed on an etching target layer of a workpiece within a decompressed processing container provided in a substrate processing apparatus such as, for example, a plasma processing apparatus in order to form a pattern on the etching target layer. Recently, an attempt has been made to etch a film containing a transition metal (hereinafter, referred to as a “transition metal film”) as the etching target layer. The film is used as a film constituting, for example, a part of a magnetic tunnel junction (MTJ) device.

For the etching of the transition metal film, an Ar ion milling method or a plasma etching method using a halogen gas has been generally used. However, the Ar ion milling method has some problems in that a fine processing is difficult to implement, and a device to be manufactured is adversely affected by etching products re-attached to the workpiece. In addition, in the plasma etching method using a halogen gas, it is necessary to carry out an etching under a high temperature environment in order to facilitate the reaction between the transition metal and the halogen, as well as to vaporize and exhaust etching products (i.e., halides). Thus, there is a problem in that a device to be manufactured is damaged by heat or plasma under the high temperature environment.

Hence, Japanese Patent Laid-Open Publication No. 2014-236096 discloses a technique of performing a dry etching using a gas containing β-diketone which has high reactivity with a transition metal. Further, Japanese Patent Laid-Open Publication No. 2012-156259 discloses a technique of performing an etching processing on a metal film formed on a surface of a workpiece by a cluster beam. Further, Japanese Patent No. 4364669 discloses a dry etching method using an ion beam. Further, Japanese Patent Laid-Open Publication No. 2014-209552 discloses a technique of performing an etching at a relatively low temperature using a neutral beam.

### DISCLOSURE OF THE INVENTION

According to an aspect, the present disclosure provides a method of anisotropically etching a transition metal film using a substrate processing apparatus including at least one processing container configured to perform a processing on a workpiece including the transition metal film. The method includes an oxidation step of introducing a first gas containing an oxygen ion into the processing container and irradiating the transition metal film with the oxygen ion to oxidize a transition metal of the transition metal film, thereby forming a metal oxide layer; and a complexation/etching step of introducing a second gas for complexation of the metal oxide layer into the processing container and forming a metal complex in the metal oxide layer, thereby performing an etching.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a flowchart of an etching method of a transition metal according to an exemplary embodiment of the present disclosure.

FIG. 2 is a vertical-sectional view illustrating a schematic configuration of a substrate processing apparatus.

FIGS. 3A to 3D are explanatory views of respective steps of the method illustrated in FIG. 1.

FIGS. 4A to 4F are structural formulas of exemplary complexation gases.

FIGS. 5A and 5B are schematic explanatory views illustrating an exemplary chamber configuration when the etching method according to the present disclosure is performed in a multiple chamber manner.

### DETAILED DESCRIPTION

In the following detailed description, reference is made to the accompanying drawing, which form a part hereof The illustrative embodiments described in the detailed description, drawing, and claims are not meant to be limiting. Other embodiments may be utilized, and other changes may be made without departing from the spirit or scope of the subject matter presented here.

In the technique disclosed in Japanese Patent Laid-Open Publication No. 2014-236096, the etching is isotropically performed. Thus, the technique may not be suitable for manufacturing semiconductor devices. Further, in the technique disclosed in Japanese Patent Laid-Open Publication No. 2012-156259, it is difficult to cope with miniaturization of devices in principle, and it is necessary to scan the wafer (workpiece) in order to increase the area thereof. Thus, the throughput may be reduced. Further, in the technique disclosed in Japanese Patent No. 4364669, since the beam incident on the substrate (workpiece) is electrically charged, shape deterioration or damage to the device may occur due to charge-up. Further, in the technique disclosed in Japanese Patent Laid-Open No. 2014-209552, since the beam is incident on the wafer (workpiece) without collision, a relatively low-pressure process is required, and a small amount of complexation gases is supplied. Therefore, the complex reaction rate may be reduced, and thus, the etching rate or the throughput may be reduced.

Accordingly, an object of the present disclosure is to provide a method of etching a transition metal film and a substrate processing apparatus capable of coping with miniaturization of devices and enhancing the etching rate or the throughput without occurring any damage to the devices, as compared with the conventional techniques, when etching the transition metal film.

According to an aspect, the present disclosure provides a method of anisotropically etching a transition metal film using a substrate processing apparatus including at least one processing container configured to perform a processing on a workpiece including the transition metal film. The method includes an oxidation step of introducing a first gas containing an oxygen ion into the processing container and irradiating the transition metal film with the oxygen ion to oxidize a transition metal of the transition metal film, thereby forming a metal oxide layer; and a complexation/etching step of introducing a second gas for complexation of the metal oxide layer into the processing container and forming a metal complex in the metal oxide layer, thereby performing an etching.

The substrate processing apparatus may further include a plasma source configured to generate plasma in the processing container. In the oxidation step, the transition metal film may be irradiated with the oxygen ion by generating plasma of the first gas.

The second gas may be a β-diketone-based gas.

The complexation/etching step may be performed under a condition in which a pressure of the gas is 0.1 kPa to 101.4 kPa and a temperature of the workpiece is 100° C. to 350° C.

The oxidation step may be performed under a condition in which the pressure of the gas is 100 Pa or less.

A cycle including the oxidation step and the complexation/etching step may be performed repeatedly.

The workpiece may have a mask on the transition metal film, and the mask may be formed of one selected from the group consisting of Si, SiO₂, and SiN.

According to another aspect, the present disclosure provides a substrate processing apparatus for anisotropically etching a transition metal film. The substrate processing apparatus includes at least one processing container configured to perform a processing on a workpiece including the transition metal film; a first gas source configured to introduce a first gas containing an oxygen ion into the processing container to irradiate the transition metal film with the oxygen ion to oxidize a transition metal of the transition metal film, thereby forming a metal oxide layer; and a second gas source configured to introduce a second gas serving as a complexation gas into the processing container to form a metal complex in the metal oxide layer, thereby performing an etching.

The substrate processing apparatus may further include a plasma source configured to generate plasma in the processing container. The transition metal film may be irradiated with the oxygen ion by generating plasma of the first gas.

The second gas may be a β-diketone-based gas.

The at least one substrate processing container may include a first processing container into which the first gas is introduced to irradiate the transition metal film with the oxygen ion so as to form a metal oxide layer, and a second processing container into which the second gas is introduced to form a metal complex in the metal oxide layer so as to perform an etching.

A volume of the first processing container may be smaller than a volume of the second processing container.

According to the present disclosure, it is possible to cope with miniaturization of devices and enhance the etching rate or the throughput without causing any damage to the devices when etching the transition metal film.

Hereinafter, an exemplary embodiment of the present disclosure will be described with reference to the drawings. In the present specification and drawings, components having substantially the same functional configurations will be denoted by the same symbols, and the overlapping descriptions thereof will be omitted.

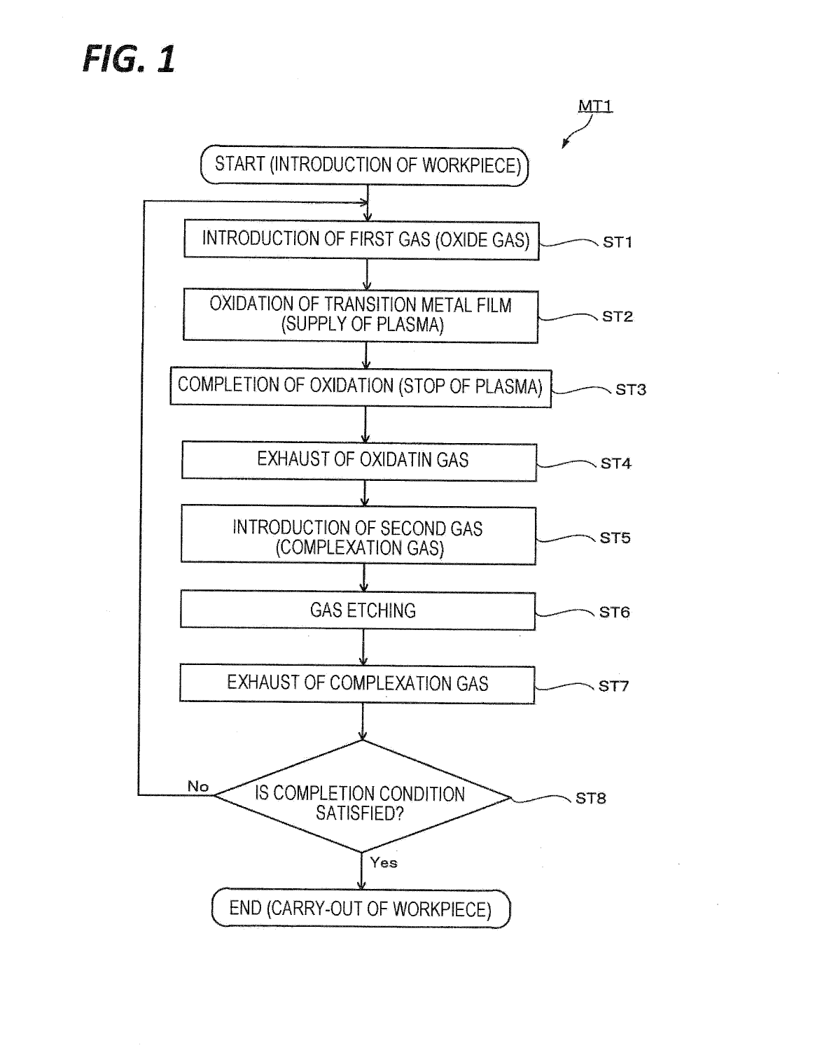

FIG. 1 is a flowchart of an etching method of a transition metal according to an exemplary embodiment of the present disclosure. As illustrated in FIG. 1, an etching method of a transition metal film MT1 according to an exemplary embodiment of the present disclosure (hereinafter, referred to as “method MT1”) includes steps ST1 to ST8. Hereinafter, respective steps will be described.

In step ST1, an oxide gas (e.g., O₂) is introduced as a first gas into a processing container which accommodates a workpiece having a transition metal film. Then, in step ST2, plasma is supplied so that plasma of the oxide gas is generated and the transition metal film is oxidized. In order to perform anisotropic oxidation, step ST2 may be performed at a pressure of 100 Pa or less. Further, in order to obtain a more vertical processing shape, step ST2 may be performed under a condition of 1 Pa or less. Although the temperature of the workpiece in step ST2 is not considered, a condition at room temperature or lower may be desirable in order to ensure anisotropy.

In the subsequent step ST3, the supply of the plasma is stopped at a stage where the oxidation of the transition metal film is completed. Subsequently, the oxide gas in the processing container is exhausted.

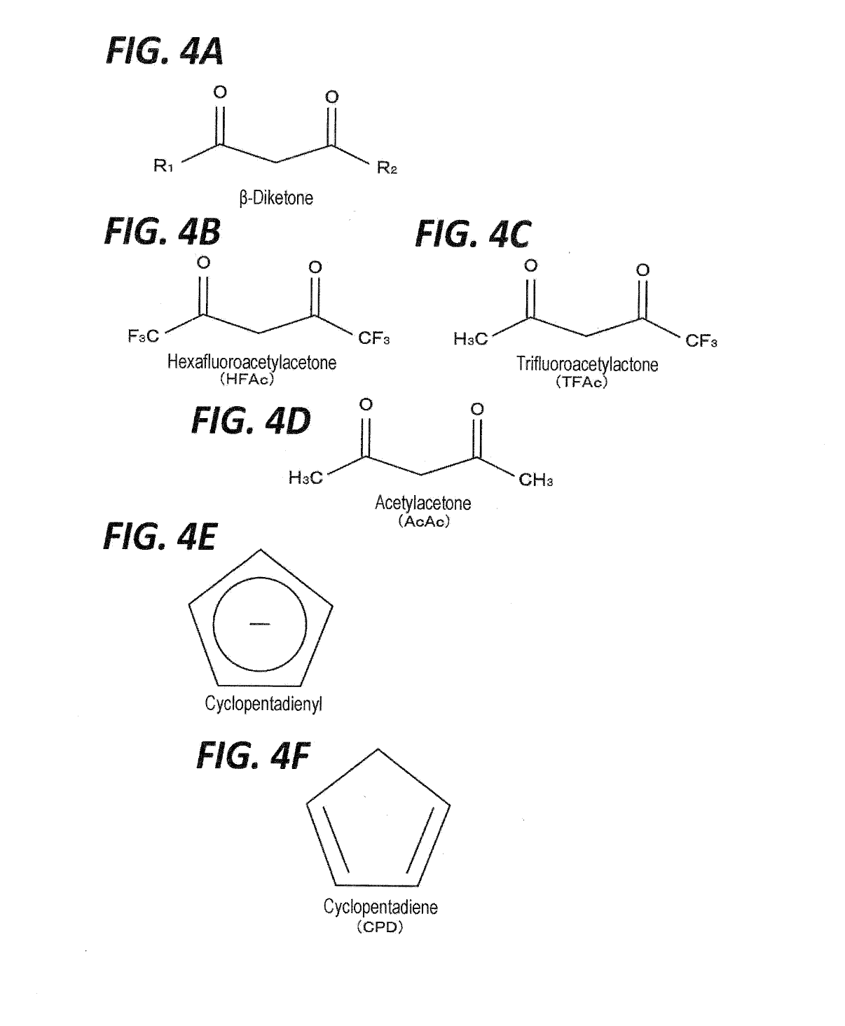

Then, in step ST5, a complexation gas is introduced as a second gas into the processing container in which the oxide gas is completely exhausted. In step ST6, a complex (metal complex) is formed from the oxidized transition metal film by the complexation gas, and an etching (gas etching) is performed. The complexation gas may be a (β-diketone-based gas which is capable of reacting with the metal to form a metal complex having a high vapor pressure. Specific examples thereof include hexafluoroacetylacetone (HFAc), trifluoroacetylactone (TFAc), and acetylacetone (AcAc). Further, the complexation gas may be a cyclopentadienyl-based gas (e.g., cylcopentadiene). FIGS. 4A to 4F are structural formulas of exemplary complexation gases.

As a condition for performing step ST6, in order to form a sufficient complex by a reaction only with the gas, the pressure of the gas may be 0.1 kPa to 101.3 kPa, more specifically 1.33 kPa to 13.3 kPa. When the pressure of the gas is lower than 0.1 kPa, the complexation gas does not sufficiently react with the metal so that the metal complex is not formed to be practically used for the etching. Further, the upper limit of the pressure of the gas is generally determined depending on the equipment conditions.

The temperature of the workpiece in step ST6 is determined depending on the target transition metal, but may be in a range of 100° C. to 350° C., more specifically 200° C. to 300° C. When the temperature is lower than 100° C., the complexation gas does not sufficiently react with the metal so that the metal complex is not formed to be practically used for the etching. Further, when the temperature exceeds 350° C., the complexation gas (e.g., β-diketone-based gas) may be decomposed.

In the subsequent step ST7, the complexation gas in the processing gas is exhausted at a stage where the etching is completed. Then, in step ST4, it is determined whether a completion condition of the etching method of the transition metal film MT1 according to the exemplary embodiment of the present disclosure is satisfied. For example, it is determined whether a cycle including steps ST1 to ST7 is performed a predetermined number of times. When the completion condition is not satisfied, the processing of steps ST1 to ST7 is repeated again. Meanwhile, when the completion condition is satisfied, method MT1 is completed by carrying the workpiece out of the processing container. The completion condition varies depending on the film thickness of the transition metal film that is an etching target, and a thick film may be etched by repeatedly performing the cycle including steps ST1 to ST7.

In method MT1, steps ST1 to ST4 correspond to the oxidation step, and steps ST5 to ST7 correspond to the complexation/etching step.

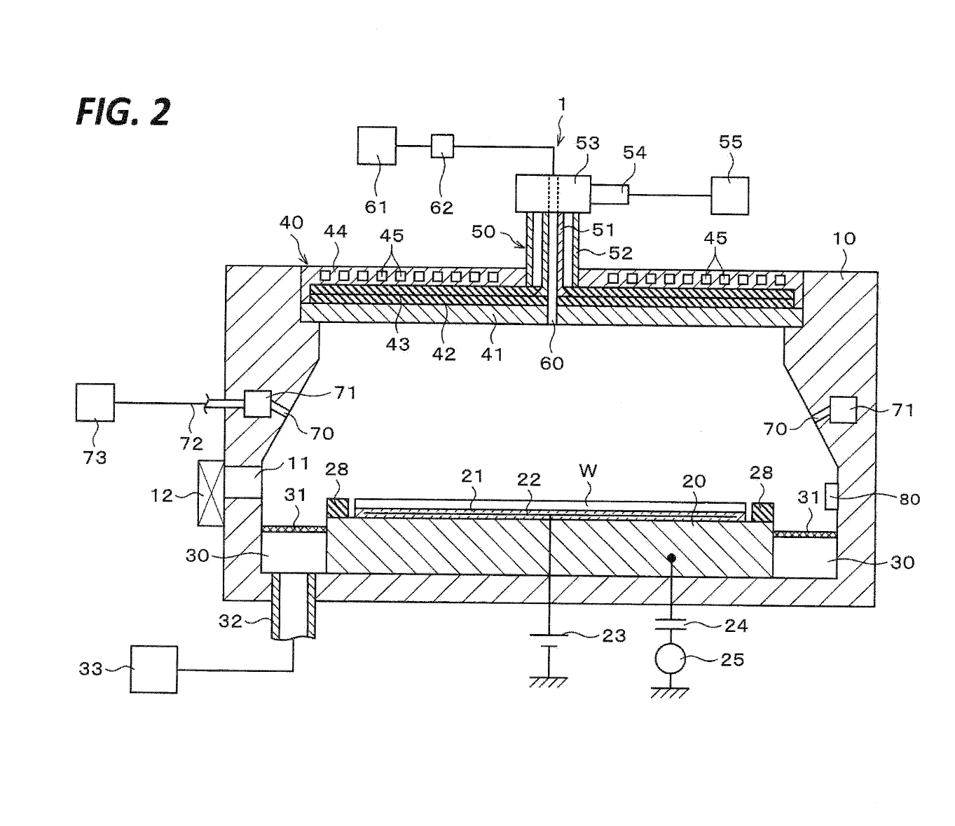

Hereinafter, descriptions will be made on an exemplary substrate processing apparatus which may be used in the etching method of the transition metal film MT1 according to the exemplary embodiment of the present disclosure as described above. FIG. 2 is a vertical-sectional view illustrating a schematic configuration of a substrate processing apparatus 1.

The substrate processing apparatus 1 includes a processing container 10 as illustrated in FIG. 2. The processing container 10 has a substantially cylindrical shape with the ceiling side opened. A radial line slot antenna 40 (to be described later) is arranged in the ceiling side opening. Further, the processing container 10 has a workpiece carry-in/out port 11 formed at a lateral side thereof. The carry-in/out port 11 is provided with a gate valve 12. And, the inside of the processing container 10 is configured to be sealable. The processing container 10 is formed of a metal such as, for example, aluminum or stainless steel. The processing container 10 is grounded.

On the bottom surface of the processing container 10, a placing table 20 is provided as a placing unit to place a wafer W (workpiece) having a transition metal film formed thereon (hereinafter, simply referred to as a “wafer W”). The placing table 20 has a cylindrical shape. In addition, the placing table 20 is formed of, for example, aluminum.

An electrostatic chuck 21 is provided on the top surface of the placing table 20. The electrostatic chuck 21 has a structure in which an electrode 22 is sandwiched between insulating materials. The electrode 22 is connected to a DC power source 23 provided outside the processing container 10. The wafer W may be electrostatically attracted onto the placing table 20 by generating a Coulomb force on the surface of the placing table 20 by the DC power source 23.

Further, the placing table 20 may be connected with a high frequency power source 25 for RF bias via a condenser 24. The high frequency power source 25 outputs high frequency waves of a constant frequency suitable for controlling the energy of the ions to be drawn into the workpiece W, for example, 13.56 MHz at a predetermined power.

An annular focus ring 28 is provided on the top surface of the placing table 20 to surround the wafer W on the electrostatic chuck 21. The focus ring 28 is formed of an insulating material such as, for example, ceramics or quartz. The focus ring 28 functions to enhance the uniformity of the plasma processing.

Further, a lift pin (not illustrated) is provided below the placing table 20 to support the wafer W from the bottom and lift the wafer W. The lift pin is inserted through a through-hole (not illustrated) formed in the placing table so as to protrude from the top surface of the placing table 20.

Around the placing table 20, an annular exhaust space 30 is defined between the placing table 20 and the lateral side of the processing container 10. An annular baffle plate 31 having a plurality of exhaust holes formed therein is provided in an upper portion of the exhaust space 30 to uniformly exhaust an atmosphere in the processing container 10. Exhaust pipes 32 are connected to the bottom surface of the processing container 10 as a bottom portion of the exhaust space 30. The number of exhaust pipes 32 may be optionally set, and a plurality of exhaust pipes 32 may be formed in a circumferential direction. Each exhaust pipe 32 is connected to an exhaust device 33 including, for example, a vacuum pump. The exhaust device 33 may decompress the atmosphere in the processing container 10 to a predetermined vacuum degree.

A radial line slot antenna 40 is provided in the ceiling side opening of the processing container 10 to supply microwaves for plasma generation. The radial line slot antenna 40 includes a microwave transmitting plate 41, a slot plate 42, a slow-wave plate 43, and a shield cover 44.

The microwave transmitting plate 41 is provided tightly in the ceiling side opening of the processing container 10 through a sealing member such as, for example, an O-ring (not illustrated). Accordingly, the inside of the processing container 10 is hermetically maintained. The microwave transmitting plate 41 is formed of a dielectric such as, for example, quartz, Al₂O₃, or AlN. The microwave transmitting plate 41 transmits the microwaves.

The slot plate 42 is provided as a top surface of the microwave transmitting plate 41 to face the placing table 20. The slot plate 42 has a plurality of slots formed therein. The slot plate 42 functions as an antenna. The slot plate 42 is formed of a conductive material such as, for example, copper, aluminum, or nickel.

The slow-wave plate 43 is provided on the top surface of the slot plate 42. The slow-wave plate 43 is formed of a low-loss dielectric material such as, for example, quartz, Al₂O₃, or AlN. The slow-wave plate 43 shortens the wavelength of the microwaves.

The shield cover 44 is provided on the top surface of the slow-wave plate 43 to cover the slow-wave plate 43 and the slot plate 42. A plurality of annular flow paths 45 are provided inside the shield cover 44 to distribute, for example, a cooling medium. The microwave transmitting plate 41, the slot plate 42, the slow-wave plate 43, and the shield cover 44 are adjusted to a predetermined temperature by the cooling member flowing through the flow paths 45.

A coaxial waveguide 50 is connected to a central portion of the shield cover 44. The coaxial waveguide 50 includes an inner conductor 51 and an outer pipe 52. The inner conductor 51 is connected to the slot plate 42. The slot plate 42 side of the inner conductor 51 is formed in a conical shape, and configured to efficiently propagate the microwaves to the slot plate 42.

The coaxial waveguide 50 is connected with a mode converter 53 that converts microwaves into a predetermined oscillation mode, and a rectangular waveguide 54, a microwave generator 55 that generates microwaves, in this order from the coaxial waveguide 50 side. The microwave generator 55 generates microwaves of a predetermined frequency (e.g., 2.45 GHz).

With the configuration, the microwaves generated by the microwave generator 55 are propagated sequentially through the rectangular waveguide 54, the mode converter 53, and the coaxial waveguide 50, supplied into the radial line slot antenna 40, and compressed by the slow-wave plate 43 to have a shorter wavelength. Then, circularly polarized waves are generated from the slot plate 42, transmitted through the microwave transmitting plate 41, and radiated into the processing container 10. A processing gas may be converted into plasma in the processing container 10 by the microwaves, and the plasma processing of the wafer W may be performed by the plasma.

A first gas supply pipe 60 serving as the first gas supply unit is provided in the central portion of the ceiling surface of the processing container 10, that is, the radial line slot antenna 40. The first gas supply pipe 60 penetrates through the radial line slot antenna 40 such that one end portion of the first gas supply pipe 60 is opened in the bottom surface of the microwave transmitting plate 41. Further, the first gas supply pipe 60 penetrates through the inside of the inner conductor 51 of the coaxial waveguide 50, and is further inserted through the mode converter 53 such that the other end portion of the first gas supply pipe 50 is connected to a first gas supply source 61.

An oxide gas (e.g., O₂) is stored within the first gas supply source 61. The first gas supply pipe 60 is provided with a supply equipment group 62 including a valve or a flow rate adjusting unit that controls the flow of the first gas. And, the first gas supplied from the first gas supply source 61 is supplied from the first gas supply pipe 60 into the processing container 10. The first gas flows vertically downwardly toward the wafer W placed on the placing table 20 in the processing container 10.

As illustrated in FIG. 2, second gas supply pipes 70 serving as the second gas supply unit are provided in the lateral side of the processing container 10. A plurality of (e.g., twenty four (24)) second gas supply pipes 70 are provided at equal intervals on the circumference of the lateral side of the processing container 10. One end portion of each second gas supply pipe 70 is opened at the lateral side of the processing container 10, and the other end portion thereof is connected to a buffer section 71. The second gas supply pipe 70 is disposed obliquely such that the one end portion is positioned below the other end portion.

The buffer section 71 is provided annularly inside the lateral side of the processing container 10, and provided in common to the plurality of second gas supply pipes 70. The buffer section 71 is connected with a second gas supply source 73 through a supply pipe 72. The second gas supply source 73 stores therein a β-diketone-based gas such as, for example, hexafluoroacetylacetone (HFAc), trifluoroacetylactone (TFAc), or acetylacetone (AcAc). The second gas may be a cyclopentadienyl-based gas (e.g., cyclopentadiene).

As illustrated in FIG. 2, the second gas supplied from the second gas supply source 73 is introduced into the buffer section 71 through the supply pipe 72. After the pressure in the circumferential direction becomes uniform in the buffer section 71, the second gas is supplied into the processing container 10 through the second gas supply pipes 70.

Further, in the substrate processing apparatus 1 according to the present exemplary embodiment, a mass spectrometer (QMS) 80 may be provided in the processing container 10. The mass spectrometer 80 detects an amount of a complex or a complexation gas present in the processing container 10, and also detects a change of the amount of the complex or the complexation gas present in the processing container 10. Based on the detection of the mass spectrometer 80, the performance of method MT1 may be ended, for example, when the amount of the complex is decreased. Alternatively, when the amount of the complexation gas is increased, the performance of method MT1 may be ended. When approaching the end point of the etching of the transition metal film, the amount of the complex present in the processing container 10 is decreased, whereas the complexation gas is not consumed by the etching. Thus, the amount of the complexation gas is increased. That is, the end point of the etching of the transition metal film may be detected by using the output signal of the mass spectrometer 80.

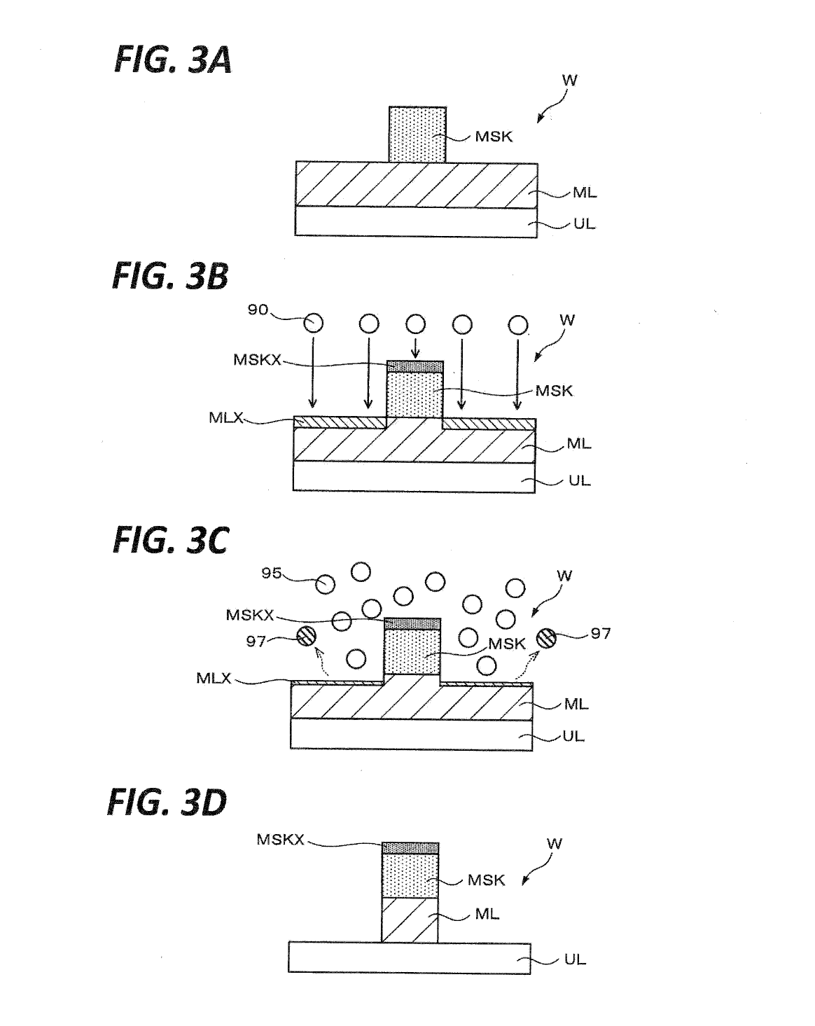

Next, the etching method of the transition metal film MT1 according to the exemplary embodiment of the present disclosure will be described in more detail with reference to FIGS. 1, 2, and 3A to 3D. FIGS. 3A to 3D are explanatory views of respective steps of method MT1 illustrated in FIG. 1. In method MT1, the wafer W is first accommodated in the processing container 10, and the wafer W is placed on the placing table 20. Here, as illustrated in FIG. 3A, the wafer W has an underlayer UL and a transition metal-containing film ML.

The film ML is provided on the underlayer UL. A mask MSK is provided on the film ML. The transition metal constituting the film ML may be, for example, tantalum (Ta), ruthenium (Ru), platinum (Pt), palladium (Pd), cobalt (Co), or iron (Fe). Further, the metal containing the film ML may be alloy such as, for example, cobalt iron boron (CoFeB), platinum manganese (PtMn), iridium manganese (IrMn), iron platinum (FePt), iron palladium (FePd), or terbium iron cobalt (TbFeCo).

Further, the mask MSK may be formed of a film such as, for example, Ta, titanium nitride (TiN), Si, SiO₂, SiN, TiN, or TaN. However, when a β-diketone-based gas is used as the complexation gas, a Si-based film may be used as the mask MSK because of the property that the β-diketone-based gas reacts with a transition metal having a 3d orbital but hardly reacts with other elements. Accordingly, the etching selection ratio of the film ML to the mask MSK may be enhanced.

Subsequently, in method MT1, a first gas (oxide gas) is supplied into the processing container 10 from the first gas supply pipe 60 serving as the first gas supply unit. In addition, plasma of the first gas is produced by microwaves generated by the microwave generator 55. Thus, as illustrated in FIG. 3B, oxygen ions 90 are irradiated onto the surface of the wafer W so that the transition metal in a portion not covered by the mask MSK of the film ML is oxidized, and the surface layer portion is changed to a metal oxide layer MLX. In addition, the oxygen ions 90 is irradiated onto the surface of the mask MSK so that the surface portion of the mask MSK is changed to a mask oxide layer MSKX.

In order to perform anisotropic oxidation, the oxidation step illustrated in FIG. 3B may be performed at a pressure of 100 Pa or less. Furthermore, in order to obtain a more vertical processing shape, the oxidation step may be performed under a condition of 1 Pa or less. Although the temperature of the wafer W at this time is not considered, in order to ensure anisotropy, a condition at room temperature or lower may be desirable.

Subsequently, in method MT1, the introduction of the first gas (oxide gas) from the first gas supply pipe 60 and the generation of the plasma is stopped, and the exhaust of the first gas is performed. The above descriptions correspond to steps ST1 to ST4 of method MT1.

Subsequently, in step ST5, a second gas (complexation gas) is supplied into the processing container 10 from the second gas supply pipe 70 serving as the second gas supply unit. Thus, as illustrated in FIG. 3C, the metal oxide layer MLX, which is not covered by the mask MSK, is exposed to a complexation gas-rich atmosphere, and molecules 95 contained in the complexation gas are adsorbed onto the metal oxide layer MLX. Then, an oxide of the transition metal contained in the metal oxide layer MLX and the molecules contained in the complexation gas react with each other to form a complex (metal complex 97). Since the mask oxide layer MSKX hardly reacts with the complexation gas, the mask MSK, and the mask oxide layer MSKX remains on the wafer W as they are.

The thus formed complex has a high vapor pressure. Particularly, when the β-diketone-based gas is used as the complexation gas, an organic metal complex having a very high vapor pressure is formed. Therefore, the formed metal complex 97 is vaporized on the wafer W, and then, gas etching proceeds as step ST6. In the complexation/etching step illustrated in FIG. 3C, in order to promote the reaction with the complexation gas-rich atmosphere in the processing container 10, the gas pressure may be set to a predetermined value or higher. Specifically, in order to form a sufficient complex, the pressure of the gas may be 0.1 kPa to 101.3 kPa, more specifically 1.33 kPa to 13.3 kPa. Further, in order to vaporize the formed metal complex 97 on the wafer W, the wafer W is required to be set at a predetermined temperature or higher. The temperature is determined depending on the target transition metal, but may be in a range of 100° C. to 350° C., more specifically 200° C. to 300° C.

Then, when the gas etching is completed as illustrated in FIG. 3D, accordingly, as step ST7, the introduction of the second gas (complexation gas) from the second gas supply pipe 70 is stopped, and the exhaust of the second gas is performed. The above descriptions correspond to steps ST5 to ST7 of method MT1.

As described above with reference to FIG. 1, the cycle including steps ST1 to ST7 may be performed a plurality of times. This is because the oxidation of the film illustrated in FIG. 3B may be achieved only in a part (surface layer portion) from the surface of the film ML in the thickness direction. The formation of the complex (complexation) in the metal oxide layer MLX illustrated in FIG. 3C may be achieved only in the oxidized metal oxide layer MLX in some cases. Thus, when only a part of the surface of the film ML is oxidized, the gas etching proceeds only in that range as well. Therefore, in order to complete the gas etching through the whole film ML in the thickness direction, it is necessary to repeat the cycle including step ST1 to ST7.

It is determined whether the gas etching is finally completed, based on, for example, the detection of the mass spectrometer (QMS) 80 provided in the processing container 10 (step ST8).

In the etching method of the transition metal film MT1 according to the exemplary embodiment of the present disclosure as described above, the oxidation step (steps ST1 to ST4) may be performed under a pressure of 100 Pa or less, more specifically under a condition of 1 Pa or less in order to obtain a more vertical processing shape. Here, the temperature of the workpiece (wafer W) is not considered.

Meanwhile, the complexation/etching step (steps ST5 to ST7) may be performed under a condition of 0.1 kPa to 101.3 kPa, more specifically a condition of 1.33 kPa to 13.3 kPa in order to form a sufficient complex. Further, the temperature of the workpiece (wafer W) may be 100° C. to 350° C., more specifically 200° C. to 300° C.

That is, since the gas etching is performed under a high-pressure high-temperature condition, the complex reaction rate is enhanced as compared with the conventional techniques, and thus, enhancement of the etching rate or the throughput is realized. In addition, since the etching is performed by vaporizing the metal complex formed using the complexation gas without using plasma in the etching, the etching may be performed without any problem such as, for example, re-attachment of etching products to the workpiece or damage to the device.

An example of the exemplary embodiment of the present disclosure has been described, but the present disclosure is not limited to the example illustrated. It should be understood that various modifications or changes that can be easily inferred by those skilled in the art within the scope and spirit described in the claims fall within the scope of the present disclosure.

For example, in the above-described exemplary embodiment, the substrate processing apparatus 1 to which the etching method according to the present disclosure (method MT1) is applied has been described with respect to a microwave plasma source using a radial line slot antenna (RLSATM) as a plasma source. However, the plasma source is not limited thereto in applying the etching method according to the present disclosure. That is, the plasma source may be applied to, for example, a parallel flat plate type (CCP or ICP) plasma processing apparatus. Further, in the oxidation step, the oxidation may be performed isotropically by irradiation with an ion beam.

Further, in the above-described exemplary embodiment, the substrate processing apparatus 1 to which the etching method according to the present disclosure (method MT1) is applied has been described by illustrating a one-chamber type apparatus. However, the apparatus configuration to which the present disclosure is applied is not limited thereto. That is, in method MT1, chambers (processing containers) for performing the oxidation step (steps ST1 to ST4) and chambers (processing chambers) for performing a complexation/etching step (steps ST5 to ST7) may be separately provided, and method MT1 may be performed using the plurality of chambers. As described above, in method MT1, the etching may be completed by repeating the cycle including steps ST1 to ST7. In that case, the cycle including steps ST1 to ST7 may be repeated by preparing a plurality of chambers for the oxidation step and the complexation/etching step, respectively, for every single cycle, and conveying the workpiece (wafer W) to the plurality of chambers in sequence.

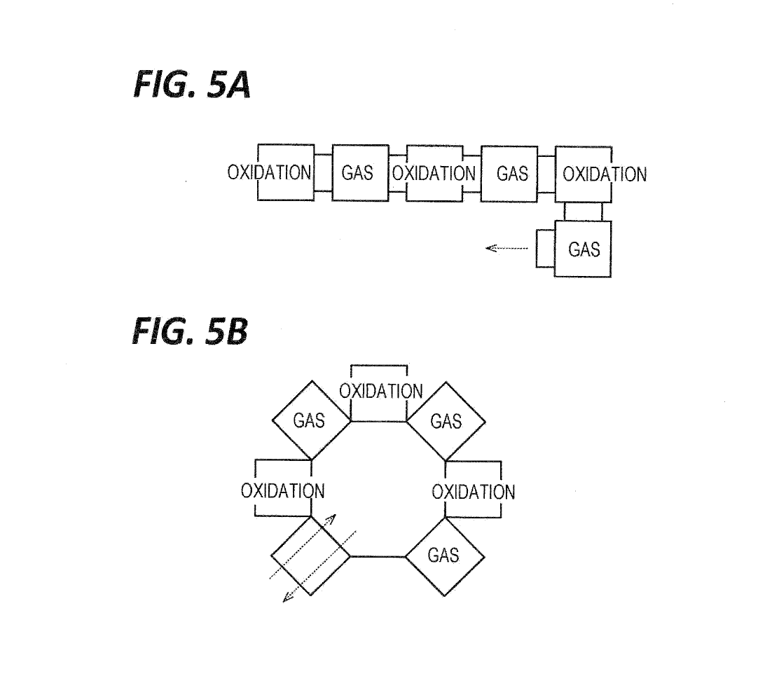

FIGS. 5A and 5B are schematic explanatory views illustrating an exemplary chamber configuration when the etching method according to the present disclosure (method MT1) is performed in a multiple chamber manner. FIG. 5A illustrates an in-line type chamber configuration, and FIG. 5B illustrates a cluster type chamber configuration.

In the in-line type multiple-chambered apparatus illustrated in FIG. 5A, chambers for performing the oxidation step (denoted as “oxidation” in the figure) and chambers for performing the complexation/etching step (denoted as “gas” in the figure) are alternately disposed adjacent to each other, and the workpiece is conveyed to the multiple chambers while performing a processing, so that the final etching is completed.

In the cluster type multiple-chambered apparatus illustrated in FIG. 5B, chambers for performing the oxidation step (denoted as “oxidation” in the figure) and chambers for performing the complexation/etching step (denoted as “gas” in the figure) are disposed in a substantially annular shape to be adjacent to each other. Then, the workpiece is conveyed to each chamber by a means such as, for example, a conveyance robot (not illustrated) positioned in the center of the entire apparatus configured in a substantially annular shape, and is subjected to processings in sequence, so that the final etching is completed. In the configurations illustrated in FIGS. 5A and 5B, the number of chambers is optional, and may be set to a number of chambers suitable to complete the final etching.

In the present disclosure, the volume of the chambers is not particularly limited in either the one-chambered configuration or the multiple-chambered configuration. However, the chamber volume (processing container volume) may be as small as possible, from the viewpoint that it is required to repeatedly perform the introduction and exhaust of various gases (including the first gas and the second gas), and in addition, it is desirable to suppress the amount of the gases used. Specifically, in the multiple-chambered configuration, the chambers for performing the complexation/etching step are required to introduce gases until the pressure becomes higher than that of the chambers for performing the oxidation step. Thus, the volume of the chambers for performing the complexation/etching step may be smaller than the volume of the chambers for performing the oxidation step.

The present disclosure may be applied to a technique of etching a transition metal film.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of anisotropically etching a transition metal film using a substrate processing apparatus including at least one processing container configured to perform a processing on a workpiece including the transition metal film, the method comprising:
an oxidation step of introducing a first gas containing an oxygen ion into the processing container and irradiating the transition metal film with the oxygen ion to oxidize a transition metal of the transition metal film, thereby forming a metal oxide layer; and
a complexation/etching step of introducing a second gas for complexation of the metal oxide layer into the processing container and forming a metal complex in the metal oxide layer, thereby performing an etching.

2. The method of claim 1, wherein the substrate processing apparatus further includes a plasma source configured to generate plasma in the processing container, and
in the oxidation step, the transition metal film is irradiated with the oxygen ion by generating plasma of the first gas.

3. The method of claim 1, wherein the second gas is a β-diketone-based gas.

4. The method of claim 1, wherein the complexation/etching step is performed under a condition in which a pressure of the gas is 0.1 kPa to 101.4 kPa and a temperature of the workpiece is 100° C. to 350° C.

5. The method of claim 1, wherein the oxidation step is performed under a condition in which the pressure of the gas is 100 Pa or less.

6. The method of claim 1, wherein a cycle including the oxidation step and the complexation/etching step is performed repeatedly.

7. The method of claim 1, wherein the workpiece has a mask on the transition metal film, and the mask is formed of one selected from the group consisting of Si, SiO₂, and SiN.

8. A substrate processing apparatus for anisotropically etching a transition metal film, the apparatus comprising:
at least one processing container configured to perform a processing on a workpiece including the transition metal film;
a first gas source configured to introduce a first gas containing an oxygen ion into the processing container to irradiate the transition metal film with the oxygen ion to oxidize a transition metal of the transition metal film, thereby forming a metal oxide layer; and
a second gas source configured to introduce a second gas serving as a complexation gas into the processing container to form a metal complex in the metal oxide layer, thereby performing an etching.

9. The substrate processing apparatus of claim 8, further comprising:
a plasma source configured to generate plasma in the processing container,
wherein the transition metal film is irradiated with the oxygen ion by generating plasma of the first gas.

10. The substrate processing apparatus of claim 8, wherein the second gas is a β-diketone-based gas.

11. The substrate processing apparatus of claim 8, wherein the at least one processing container separately includes:
a first processing container into which the first gas is introduced to irradiate the transition metal film with the oxygen ion so as to form a metal oxide layer, and
a second processing container into which the second gas is introduced to form a metal complex in the metal oxide layer so as to perform an etching.

12. The substrate processing apparatus of claim 11, wherein a volume of the first processing container is smaller than a volume of the second processing container.
